(19) United States
(12) Patent Application Publication
(10) Pub. No.: US 2010/0059265 A1
(43) Pub. Date: Mar. 11, 2010

(54) CONTACT OF SEMICONDUCTOR DEVICE AND MANUFACTURING METHOD THEREOF

(76) Inventor: Myung-Soo Kim, Gangnain-gu (KR)

Correspondence Address: SHERR & VAUGHN, PLLC, 620 HERNDON PARKWAY, SUITE 320, HERNDON, VA, 20170, US

(21) Appl. No.: 12/549,633

(22) Filed: Aug. 28, 2009

(30) Foreign Application Priority Data
Sep. 11, 2008 (KR) 10-2008-0089839

(51) Int. Cl. H05K 1/11; H05K 3/10

(52) U.S. Cl. 174/264; 29/846

(57) ABSTRACT

A contact of semiconductor device and manufacturing method thereof prevent generation or inlet of noise through a contact plug which connects wires in different layers. The contact includes a lower wire, an insulating layer covering the lower wire, a contact plug connected to the lower wire through the insulating layer, a conductive tube encircling the contact plug and having the insulating layer in between, and an upper wire connected to the contact plug.

The present application claims priority under 35 U.S.C. 119 to Korean Patent Application No. 10-2008-0089839 (filed on Sep. 11, 2008), which is hereby incorporated by reference in its entirety.

### BACKGROUND

Generally, a semiconductor device is manufactured by several distinct processes such as oxidation, etching, and ion implantation. In order to connect multiple semiconductor layers generated by the distinct processes, contact holes and contact plugs may be formed.

Contact holes may be formed by a photolithography process. A photolithography process may be performed by optically exposing and developing a photosensitive layer, coated over a wafer, using a mask on which patterns to be etched are homologously formed. The areas exposed by the developed photosensitive layer may then be etched.

A contact hole formed by etching may be filled by metals such as tungsten (W) or copper (Cu), and a metal filling formed in this manner is called a contact plug. The contact hole and contact plug are used to electrically connect lower and upper wires. Since a contact hole may be formed as a circular hole, the contact plug will have a cylinder shape.

In a semiconductor device which uses a high frequency analog signal, such as an RF transmission device, a good deal of electrical noise may be generated by or flow in through the contact plug. For example, current flowing through the contact plug creates electromagnetic waves which are not desired, and the electromagnetic waves act as noise on wires around the contact plug. In addition, the contact plug may absorb various electromagnetic waves from outside to cause an influx of noise into the wires connected to the contact plug.

### SUMMARY

Embodiments relate to contacts in a semiconductor, and a manufacturing method thereof. In particular, embodiments relate to contacts in semiconductor devices, and corresponding manufacturing methods, for preventing generation and influx of noise through a contact plug which connects wires in different layers.

In accordance with embodiments, there is provided a contact of a semiconductor device, which may include a lower wire formed over a semiconductor substrate, an insulating layer covering the lower wire, a contact plug connected to the lower wire through the insulating layer, a conductive tube encircling at least a portion of the contact plug (the insulating layer extending in between the conductive tube and the contact plug), and an upper wire formed over the insulating layer and connected to the contact plug.

In accordance with embodiments, there is provided a contact manufacturing method of a semiconductor device, which may include forming a lower wire over a semiconductor substrate, forming a middle insulating layer to cover the lower wire, forming a photosensitive pattern over the middle insulating layer, etching a portion of the middle insulating layer exposed by the photosensitive pattern to form a contact hole and a tube hole (with the tube hole formed around an outer circumferential edge of the contact hole), filling the contact hole and the tube hole with metal to form a contact plug and conductive tube, forming an upper insulating layer over the contact plug and the conductive tube; and forming an upper wire over the upper insulating layer, with the upper wire connected to the contact plug.

### DRAWINGS

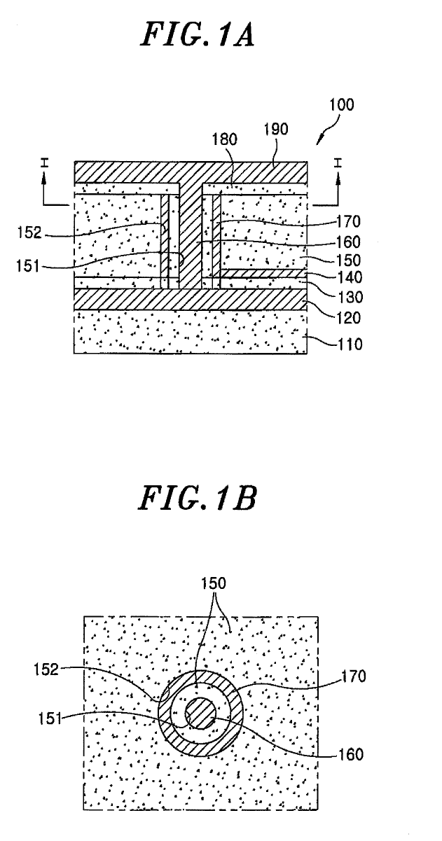

Example FIG. 1A is a cross sectional view of a contact of a semiconductor device according to embodiments.

Example FIG. 1B is a plan view of the contact of the semiconductor device cut away along line I-I in example FIG. 1A.

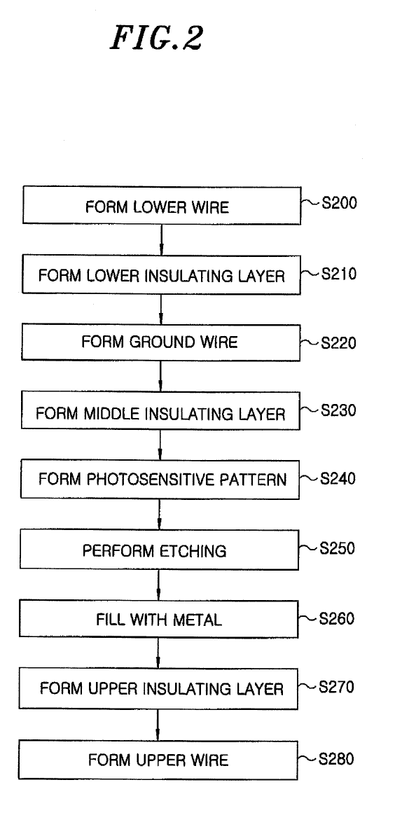

Example FIG. 2 is a flow chart of a manufacturing method for a contact of a semiconductor device according to embodiments.

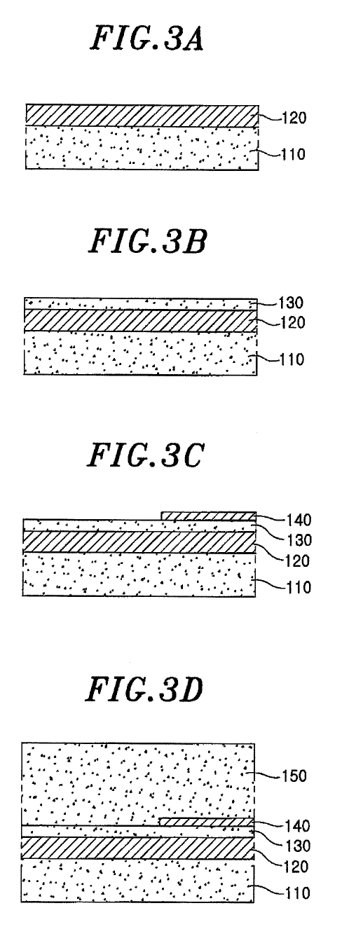

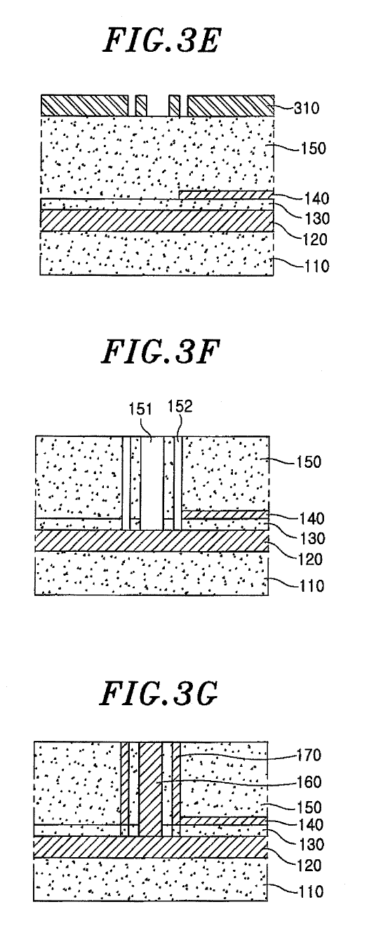

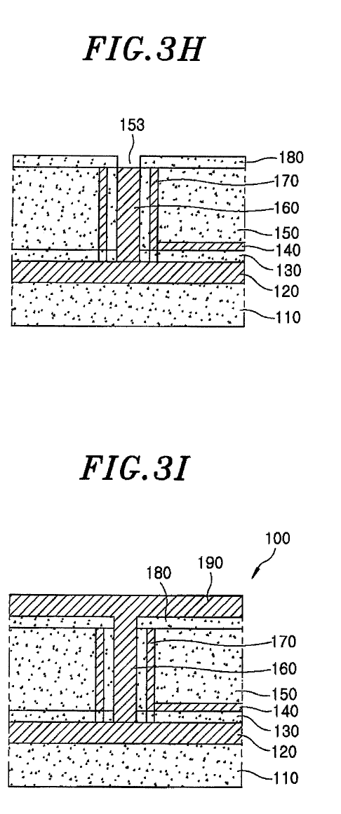

Example FIGS. 3A to 3I are cross-sectional views of a manufacturing method for a contact of a semiconductor device according to embodiments.

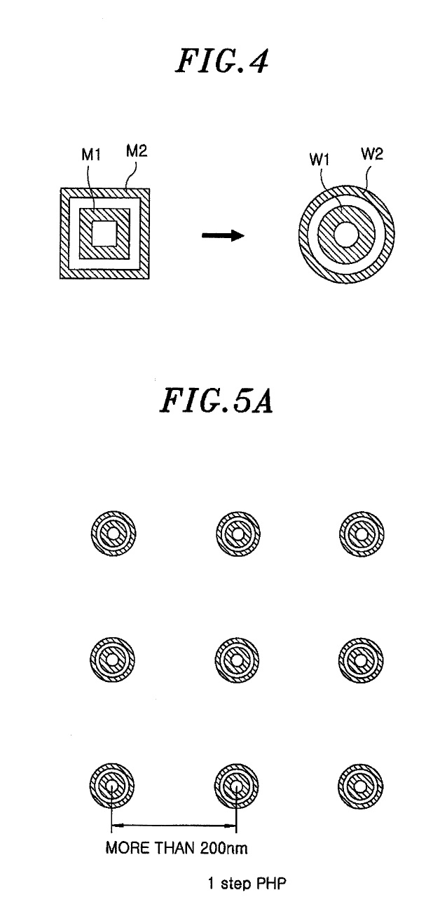

Example FIG. 4 is a plane view of an image formed on a mask and wafer, in order to form a contact according to embodiments.

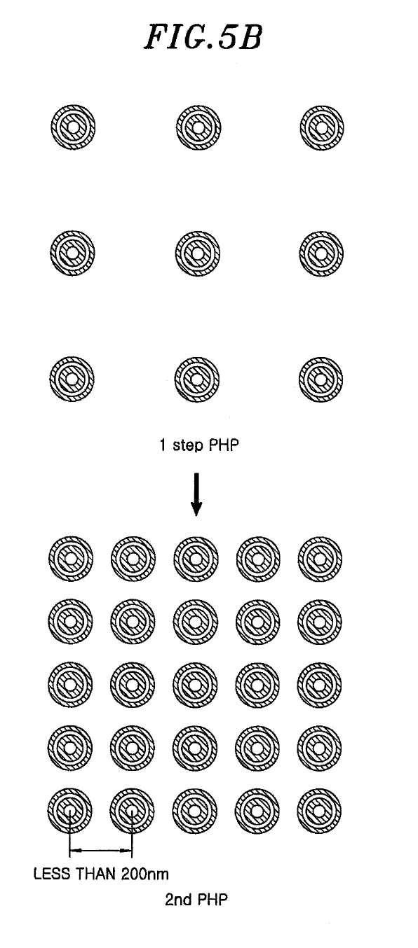

Example FIG. 5A illustrates a concept of a 1 step photo etching process.

Example FIG. 5B illustrates a concept of a 2 step photo etching process.

### DESCRIPTION

Example FIG. 1A is a cross sectional view of a contact of semiconductor device according to embodiments, and example FIG. 1B is a plan view of the contact of semiconductor device cut away along line I-I in example FIG. 1A.

As illustrated in example FIGS. 1A and 1B, a contact 100 of semiconductor device may include a base insulating layer 110, a lower wire 120 formed over the base insulating layer 110, a lower insulating layer 130 formed over the lower wire 120, a ground wire 140 formed over the lower insulating layer 130, a middle insulating layer 150 formed over the ground wire 140, a contact plug 160 formed through the middle insulating layer 150, a conductive tube 170 connected to the ground wire 140 through the middle insulating layer 150 while being coaxial with the contact plug 160, an upper insulating layer 180 formed over the middle insulating layer 150, and an upper wire 190 formed over the upper insulating layer 180 and connected with the contact plug 160.

The base insulating layer 110 may be formed over a semiconductor substrate in which transistor(s), diode(s), and/or capacitor(s) may be formed. A material of the base insulating layer 110 may be any one of oxide film, nitride film, USG (Undoped Silcate Glass), PSG (Phospho Silicate Glass), BPSG (Boro-Phospho Silicate Glass), TEOS (Tetraethyl Orthosilicate), and other similar materials, but are not limited to those materials. The lower wire 120 formed over the base insulating layer 110 may be made of any one of aluminum (Al), copper (Cu), and other similar materials. A material used for the lower insulating layer 130 formed over the lower wire 120 may include, but is not limited to, oxide film, nitride film, USG, PSG, BPSG, TEOS, or other materials of a similar character. The ground wire 140 formed over the lower insulating layer 130 may be made of any one of aluminum (Al), copper (Cu) and other materials of a similar character.

The middle insulating layer 150 may be formed over the ground wire 140 and lower insulating layer 130. A material used in the middle insulating layer may be oxide film, nitride film, USG, PSG, BPSG, TEOS or other similar materials, but it is not limited to those mentioned above. Also, a contact hole 151 may be formed through the lower insulating layer 130 and the middle insulating layer 150. The tube hole 152 may be formed through the middle insulating layer 150, coaxial with the contact hole 151 on an outer circumferential edge of the contact hole 151.

The contact plug 160 may be formed inside the contact hole 151, and thus be connected to the lower wire 120 through the lower insulating layer 130 and middle insulating layer 150. The conductive tube 170 may be formed inside the tube hole 152, coaxial with contact plug 160 and may be connected to the ground wire 140. Here, the conductive tube 170 is separated from the lower wire 120, having the lower insulating layer 130 in between. The contact plug 160 and the conductive tube 160 may be made of any one of tungsten (W), copper (Cu), aluminum (Al) and other similar materials, but not limited to those mentioned materials.

The upper insulating layer 180 formed over the middle insulating layer 150 may be made of any one of an oxide film, nitride film, USG, PSG, BPSG, TEOS, and other similar materials, but not limited to those mentioned materials. The upper wire 190 may be formed over the upper insulating layer 180 and may be connected to the contact plug 160. Thus, the upper wire 190 and the lower wire 120 may be electrically connected through the contact plug 160. In addition, the upper wire 190 and the conductive tube 170 may be separated by the upper insulating layer 180. That is, the lower part of the conductive tube 170 may be separated from the lower wire 120 by the lower insulating layer 130, and the upper part of the conductive tube 170 may be separated from the upper wire 190 by the upper insulating layer 180. Therefore, the length of the conductive tube 170 may be shorter than that of the contact plug 160. The thickness of the lower insulating layer 130 and the upper insulating layer 180 may be less than that of the middle insulating layer 150.

In the contact 100 of the semiconductor device, the contact plug 160 may be wrapped in the conductive tube 170, and the middle insulating layer 150 may be arranged in between the contact plug 160 and the conductive tube 170. Moreover, the conductive tube 170 may be connected to the ground wire 140. With this configuration of the contact 100, noise generated from the contact plug 160 is not released to outside. Noise from outside cannot flow into the contact plug 160. Thus, the contact 100 according to embodiments is less affected by noise on a semiconductor device using a high frequency analog signal similar to an RF transmission device.

Example FIG. 2 is a flowchart illustrating the manufacturing method of the contact of a semiconductor device according to embodiments. As illustrated in example FIG. 2, a contact manufacturing method of a semiconductor device may include forming a lower wire 120 in step S200, forming a lower insulating layer 130 in step S210, forming a ground wire 140 in step S220, forming a middle insulating layer 150 in step S230, forming a photosensitive pattern in step S240, etching in step S250, filling with metal in step S260, forming an upper insulating layer 180 in step S270, and forming an upper wire 190 in step S280.

Example FIGS. 3A to 3I are cross-sectional views of the contact manufacturing method for a semiconductor device shown in example FIG. 2. As illustrated in example FIG. 3A, in step S200 of example FIG. 2, a lower wire 120 may be formed over the surface of a base insulating layer 110. Here, the base insulating layer 110 may be composed of any one of oxide film, nitride film, PSG, BPSG, TEOS and other similar materials. And the lower wire 120 may be any one of aluminum (Al), copper (Cu) and other similar materials.

As illustrated in example FIG. 3B, in step S210 of example FIG. 2, a lower insulating layer 130 with a predetermined thickness may be formed over the surface of the lower wire 120. Here, the lower insulating layer 130 may be one of oxide film, nitride film, USG, PSG, BPSG, TEOS or other similar materials, but it is not limited to those mentioned above. As illustrated in example FIG. 3C, in step S220 of example FIG. 2, a ground wire 140 with a predetermined thickness may be formed over a portion of the lower insulating layer 130. Here, the ground wire 140 may be made of any one of aluminum, copper, or other similar materials, but it is not limited to those mentioned above.

As illustrated in example FIG. 3D, in step S230 of example FIG. 2, a middle insulating layer 150 with a predetermined thickness may be formed over the ground wire 140. Here, the middle insulating layer 150 may be an oxide film, nitride film, USG, PSSG, BPSG, TEOS, or other similar materials, but it is not limited to those mentioned above. As illustrated in example FIG. 3E, in step S240 of example FIG. 2, a photosensitive pattern 310 of a predetermined shape may be formed by applying, exposing, and developing a photosensitive layer over the middle insulating layer 150. Using this photosensitive pattern 310, some areas of the middle insulating layer 150 may be exposed.

As illustrated in example FIG. 3F, in step S250 of example FIG. 2, a portion of the middle insulating layer 150 exposed by the photosensitive pattern 310 may be etched, thereby forming contact hole 151 and tube hole 152 on the outer circumferential edge of the contact hole 151. Here, the etching may continue until the lower wire 120 is exposed to outside. After performing etching on the middle insulating layer 150, the photosensitive pattern 310 may also be removed by etching.

As illustrated in example FIG. 3G, in step S260 of example FIG. 2, the contact hole 151 and the tube hole 152 may be filled with metal, for example, with any one of tungsten (W), copper (Cu), aluminum (Al) and other similar materials. In this connection, the contact plug 160 may be formed in the contact hole 151, and the conductive tube 170 may be formed in the tube hole 152. And the contact plug 160 may be connected to the lower wire 120. Next, through a planarization process such as CMP (Chemical Mechanical Polishing), the upper surface may be planarized.

Before filling the holes 151 and 152 with metal, the tube hole 152 may first be filled by a predetermined amount of an insulating layer. Thus, the conductive tube 170 formed in the tube hole 152 may be separated from the lower wire 120 by the above insulating layer. And the conductive tube 170 may be connected to the ground wire 140.

As illustrated in example FIG. 3H, in step S270 of example FIG. 2, the upper insulation layer 180 may be formed over the middle insulating layer 150. Here, the contact plug 160 may be exposed through the middle of insulating layer 150. In other words, by forming an opening 153 in a portion of the upper insulating layer 180, the contact plug 160 may be exposed. And the conductive tube 170 may be covered with the upper insulating layer 180.

As illustrated in example FIG. 3I, in step S280, an upper wire 190 of a predetermined thickness may be formed over the upper insulating layer 180. Since the upper insulating layer 180 has an opening to expose the contact plug 160, the upper wire 190 may be connected to the contact plug 160 through the opening. And the upper wire 190 may be separated from the conductive tube 170 by the upper insulating layer 180.

Through the process described above, a contact 100 in a semiconductor device may be manufactured. The contact plug 160 may be wrapped with the conductive tube 170, with insulating layers in between. Moreover, the conductive tube 170 may be connected to ground wire 140. Thus, noise generated by current flowing through contact plug 160 may be absorbed by the conductive tube 170 so that the noise does not propagate outside. Noise from the outside may also be absorbed by the conductive tube 170, so is not transmitted to the contact plug 160.

Example FIG. 4 is a plane view of an image formed on a mask and wafer for forming a contact according to embodiments. As illustrated in example FIG. 4, a mask pattern used in the photosensitive pattern forming step may be different from a photosensitive pattern formed over a wafer, in reality. On the mask are a first rectangular pattern M1 and a second rectangular pattern M2 outside and separated from the first rectangular pattern M1.

When patterns are formed over the photosensitive layer using the mask, the first circular pattern W1 and the second circular pattern W2 separated from the first circular pattern W1 may be formed on the surface of the wafer. And the first circular pattern W1 and the second circular pattern W2 may be coaxial.

In this way, while rectangular patterns may be formed on the mask, circular patterns are formed on the wafer, because of a fine transfer area which is over a limiting resolution and diffraction effect of light when exposed. Thus, in order to eliminate pattern distortion generated by high resolution and light diffraction effect, rectangular patterns may be formed instead of the circular patterns.

Example FIG. 5A illustrates a concept of a one step photo etching process and example FIG. 5B illustrates a concept of a two step photo etching process. As illustrated in example FIG. 5A, if the pitch between patterns (here, the pattern is a contact hole pattern) is over 200 nm, 1 step photo etching process is applied and all patterns are formed in one step.

However, as illustrated in example FIG. 5B, if the pitch between patterns is less than 200 nm, 2 step photo etching process is applied, and patterns are formed over a plurality of steps, for example, two steps. If the pitch between patterns is below 200 nm and 1 step photo etching process is used, many errors may occur in patterns because of the limiting resolution.

Thus, in the above case, a photo etching process may be executed once to form first patterns having pitch above 200 nm and the photo etching process is executed again on the first patterns to create new patterns. In this way, patterns with pitch below 200 nm can be easily manufactured.

With contacts for a semiconductor device and a manufacturing method according to embodiments, by forming a conductive tube surrounding a contact plug and connected to a ground wire, over an outer circumferential edge of the contact plug which electrically connects a lower wire and an upper wire, noise generated from a contact plug cannot be emitted to the outside, and noise from outside cannot flow into the contact plug. Thus, embodiments can prevent various negative effects caused by noise on a semiconductor device which uses high frequency analog signals similar to a RF transmission device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a lower wire formed over a semiconductor substrate;
an insulating layer covering the lower wire;
a contact plug connected to the lower wire through the insulating layer;
a conductive tube encircling at least a portion of the contact plug, the insulating layer extending in between the conductive tube and the contact plug; and
an upper wire formed over the insulating layer and connected to the contact plug.

2. The apparatus of claim 1, wherein a length of the conductive tube is shorter than a length of the contact plug.

3. The apparatus of claim 1, wherein a lower part of the conductive tube is separated from the lower wire by the insulating layer.

4. The apparatus of claim 1, wherein an upper part of the conductive tube is separated from the upper wire by the insulating layer.

5. The apparatus of claim 1, wherein a ground wire is formed over a portion of the insulating layer and connected to the conductive tube.

6. The apparatus of claim 1, wherein the conductive tube is formed with one of tungsten, copper, and aluminum.

7. The apparatus of claim 6, including a plurality of contact plugs and conductive tubes, lower wires, and upper wires.

8. The apparatus of claim 1, wherein the conductive tube is electrically insulated from the contact plug.

9. A method comprising:
forming a lower wire over a semiconductor substrate;
forming a middle insulating layer to cover the lower wire;
forming a photosensitive pattern over the middle insulating layer;
etching a portion of the middle insulating layer exposed by the photosensitive pattern to form a contact hole and a tube hole, the tube hole formed around an outer circumferential edge of the contact hole;
filling the contact hole and the tube hole with metal to form a contact plug and conductive tube;
forming an upper insulating layer over the contact plug and the conductive tube; and
forming an upper wire over the upper insulating layer, the upper wire connected to the contact plug.

10. The method of claim 9, including:
between said forming a lower wire and said forming a middle insulating layer,
forming a lower insulating layer over the lower wire; and
forming a ground wire over a portion of the lower insulating layer, wherein the ground wire is covered with the middle insulating layer.

11. The method of claim 10, including:
after said etching, forming an insulating layer in a lower part of the tube hole, so that the contact plug is connected to the lower wire and the conductive tube is formed separated from the lower wire after said filling the contact hole and the tube hole with metal.

12. The method of claim 1O, including:
after said forming the upper insulating layer, etching a portion of the upper insulating layer corresponding to the contact plug to eliminate the portion so that the upper wire is connected to the contact plug and separated from the conductive tube.

13. The method of claim 10, wherein the conductive tube is connected to the ground wire.

14. The method of claim 9, wherein said forming the photosensitive pattern includes using a mask having a first rectangular line pattern and a second rectangular line pattern, the second rectangular pattern surrounding the first rectangular pattern and separated from the first pattern.

15. The method of claim 9, including forming a plurality of contact plugs and conductive tubes, lower wires, and upper wires, wherein a minimum spacing between centers of adjacent contact plugs defines a pitch of the contact holes.

16. The method of claim 15, wherein said forming the photosensitive pattern includes forming all of the photosensitive pattern in one step if the pitch of the contact holes is greater than 200 nm.

17. The method of claim 15, wherein said forming the photosensitive pattern includes forming the photosensitive pattern in sequence over a plurality of steps if the pitch of the contact holes is less than 200 nm.

18. The method of claim 9, wherein said filling the contact hole and the tube hole with metal includes filling with one of tungsten, copper, and aluminum.

19. The method of claim 9, wherein the tube hole is formed coaxially with the contact hole.

20. The method of claim 9, wherein the conductive tube is formed to be electrically insulated from the contact plug.
